(19) United States
(12) Patent Application Publication
(10) Pub. No.: US 2025/0254965 A1
(43) Pub. Date: Aug. 7, 2025

(54) LATERAL METAL OXIDE SEMICONDUCTOR DEVICE

(71) Applicant: Taiwan Semiconductor Manufacturing Company, LTD., Hsinchu (TW)

(72) Inventors: Chia-Cheng Ho, Hsinchu (TW); Kaochao Chen, Hsinchu (TW); Chia-Yu Wei, Hsinchu (TW)

(21) Appl. No.: 18/430,844

(22) Filed: Feb. 2, 2024

(51) Int. Cl. H01L 29/423; H01L 29/40; H01L 29/66; H01L 29/78

(52) U.S. Cl. CPC H10D 64/516; H10D 30/0281; H10D 30/65; H10D 64/01

(57) ABSTRACT

In fabricating a lateral metal oxide semiconductor (MOS) device, source and drain regions are formed in a base semiconductor. A gate oxide layer is disposed on the base semiconductor, and a gate layer on the gate oxide layer. Photolithographically patterned etching of the gate layer forms a first side of the gate facing the source. Photolithographically patterned etching of the gate layer forms a second side of the gate facing the drain of the lateral MOS device, and also etches a cavity extending partway underneath the second side of the gate. A dielectric layer is formed at least on the first and second sides of the gate and filling the cavity extending partway underneath the second side of the gate.

### BACKGROUND

The following relates to the semiconductor fabrication arts, to lateral metal-oxide-semiconductor (MOS) devices and fabrication thereof, lateral double-diffused MOS devices and fabrication thereof, to high power electronics, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 diagrammatically illustrate a side sectional view (FIG. 1) and a top view (FIG. 2) of a lateral MOS device.

FIGS. 3A, 3B, 3C, 3D, 3E, 3F, 3G, 3H, 3I, and 3J diagrammatically illustrate side sectional views of the gate region of a lateral MOS device at successive fabrication stages.

FIG. 4 diagrammatically illustrates a side sectional view of the gate region of a lateral MOS device having indicated dimensions.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Lateral metal-oxide-semiconductor (MOS) devices are used in various applications. For example, lateral double-diffused MOS (LDMOS) devices are commonly used for high power circuits and devices such as in microwave power amplifiers, RF power amplifiers, audio amplifiers, and other types of amplifiers, and find application in diverse systems such as cellular devices. An advantage of a lateral MOS device for high power applications is that they have a high breakdown voltage, e.g., above 50 volts in some designs. Double-diffusion or other dopant profile designs provide flexibility in designing the doping profile to accommodate high electric fields in a power device.

In LDMOS designs, breakdown at the breakdown voltage typically happens on the gate-to-drain side of the LDMOS device. In the case of a silicon device, the electric field at which breakdown occurs is typically around 3×10⁵ V-cm⁻¹. One way to enhance the breakdown voltage is to increase the gate-to-drain length so that the voltage drop is spread over a longer length thereby reducing the peak electric field. However, this increases the footprint of the device, thus reducing LDMOS device array density and increasing wafer cost.

In LDMOS device simulations, it was found that the peak electric field at the time of breakdown typically occurs in the vicinity of the side of the gate that faces the drain of the LDMOS device. In the simulations, breakdown happened in the n/p depletion region around the gate edge at the drain-facing side of the gate. The simulations were analyzed as to key performance indicators including hot carrier injection (HCl) and HCl-time dependent dielectric breakdown (HCl-TDDB).

Typically, a dielectric layer is disposed on the sidewall of the gate, e.g., encircling or circumferentially coating the sidewall of the gate. As disclosed herein, the breakdown voltage can be increased by including an extension of this dielectric layer that extends partway underneath the drain-facing side of the gate. For example, in some embodiments the extension of the dielectric layer is disposed between the bottom of the drain-facing side of the gate and the underlying gate oxide. The extension of the dielectric layer reduces the electric field at the edge of the gate, thereby increasing the breakdown voltage. This improvement in the breakdown voltage is advantageously attained without increasing the gate-to-drain length of the LDMOS device or otherwise modifying the LDMOS design. While described herein with respect to an LDMOS device, this improvement is expected to be attained for other types of lateral MOS devices.

Further disclosed herein is a fabrication method that enables self-aligned formation of the dielectric layer disposed on the sidewall of the gate and the extension of this dielectric layer partway underneath the drain-facing side of the gate. The disclosed approach leverages a two-step etch process to pattern the gate from a deposited gate layer. The two-step etch process includes a sequence of first and second etches. The first etch removes an upper portion of a gate layer to expose an upper portion of the drain-facing side of the gate while leaving a thinned portion of the gate layer extending laterally away from the (at this point incompletely exposed) drain-facing side of the gate. The first etch is an anisotropic dry etch providing high aspect ratio etching, such as reactive ion etching (RIE) or deep reactive ion etching (DRIE). The first dry etch is performed with etch parameters (e.g., radio frequency (RF) field) chosen to provide the high aspect ratio anisotropic etching. The first etch is then followed by a second etch which is isotropic, or is less anisotropic (i.e., provides less high aspect ratio etching) than the first etch. The second etch removes the remaining thinned portion of the gate layer to fully expose the drain-facing side of the gate, and also removes a portion of the gate layer underneath the drain-facing side of the gate to form the cavity extending partway underneath the drain-facing side of the gate. By controlling the etch time of the first etch, the thickness of the remaining thinned portion of the gate layer is controlled. By controlling the etch parameters of the second etch the amount of etch anisotropy (or, in the limit, isotropic etching) is obtained to obtain the cavity extending partway underneath the drain-facing side of the gate with desired dimensions. After the second etch is complete, the dielectric layer is formed, for example by chemical vapor deposition (CVD) or thermal oxidation or so forth, with the dielectric layer being formed both on the sidewall of the gate and inside the cavity extending partway underneath the drain-facing side of the gate to fill the cavity and thereby form the extension of this dielectric layer partway underneath the drain-facing side of the gate.

This process has substantial advantages. The modification to the fabrication process workflow to obtain the extension of the dielectric layer partway underneath the drain-facing side of the gate is minimal. For example, in one nonlimiting illustrative example, the modification entails changing one or more etch parameters during a dry etch process forming the drain-facing side of the gate to provide the desired reduction in anisotropy (i.e., reduction in the aspect ratio of the etching) to switch from the first etch process to the second etch process. Alternatively, two different etch processed scan be used, such as the first etch process being an anisotropic dry etch and the second etch process being an isotropic wet etching process. The dielectric material of the extension is the same as the dielectric material of the dielectric layer coating the gate sidewall, which provides a robust fabrication process and expected high yield.

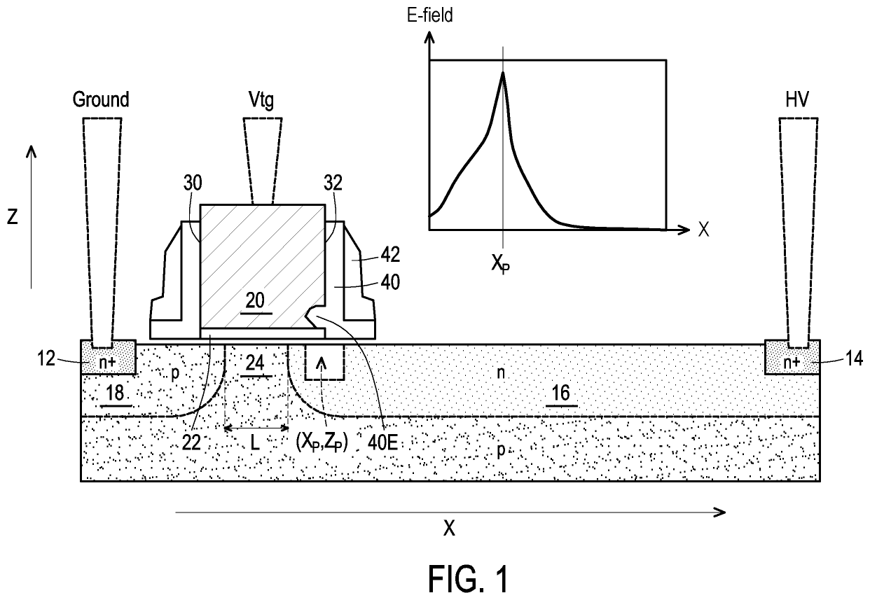

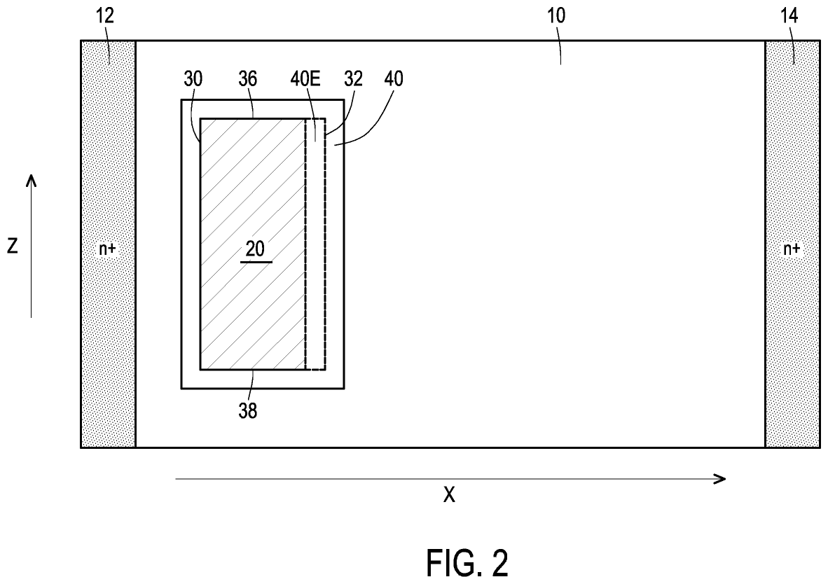

With reference to FIGS. 1 and 2, a lateral MOS device is diagrammatically shown by way of a side sectional view (FIG. 1) and a top view (FIG. 2), respectively. The lateral MOS device is fabricated on a base semiconductor 10. The base semiconductor can be a silicon wafer, the silicon layer of a silicon-on-insulator (SOI) wafer, an epitaxial silicon layer deposited on a semiconductor wafer, or so forth. While silicon-based lateral MOS devices are described as an example, more generally the lateral MOS device could be fabricated in another semiconductor material system such as silicon-germanium other group IV alloys (e.g., SiC), gallium arsenide (GaAs) or other group III-group V materials (e.g., GaAs, GaP, Al,Ga₍₁₋ₓ₎As, GaN, or so forth), various combinations thereof, or so forth. In some embodiments, the base semiconductor 10 has a doping level, for example a p-type doping level is employed in an illustrative embodiment herein.

Suitable doping of the base semiconductor 10 is performed to form n-type and/or p-type doped regions and/or spatially varying doping profiles of the lateral MOS. For example, n-type doping may be performed to form a source (or source region) 12 of the lateral MOS device and a drain (or drain region) 14 of the lateral MOS device. As diagrammatically indicated only in FIG. 1, in one nonlimiting illustrative example, the lateral MOS device is a lateral double-diffused MOS (LDMOS) device that includes a double-diffused n′/n doped region in which a larger n-type region 16 (also called a drift region 16 herein) is formed by a first n-type dopant diffusion process, followed by a second n-type dopant diffusion process to form the n′ drain 14 within the n-type drift region 16. Optionally, the n source region 12 may be formed in the same dopant diffusion process that forms the n′ drain region 14. The notation of an n′ drain 14 within an n-type drift region 16 indicates the n-type doping concentration of the drain 14 is higher than the n-type doping concentration of the n-type doped drift region 16. A p-type well or body region 18 is optionally formed by a p-type diffusion into the base semiconductor 10 to produce the p-type well 18 with a higher p-type doping concentration than the p-type doping concentration of the base semiconductor 10.

As further seen in FIGS. 1 and 2, a gate 20 is interposed between the source 12 and drain 14. The gate 20 is disposed on a gate oxide 22 which in turn is disposed on the base semiconductor 10. A lateral channel region 24 of length L (indicated only in FIG. 1) is located between the p-type well 18 and the n-type drift region 16. In one suitable mode of operation, the source 12 is grounded, the drain 14 has a high voltage (HV) applied, and a control voltage (Vtg) is applied to the gate 20 to modulate electrical current flow between the source 12 and drain 14 via the channel 24.

It will be appreciated that the doping regions 16, 18 illustrated in FIG. 1 are nonlimiting illustrative examples, and the disclosed approach of including an extension of the gate sidewall-coating dielectric layer that extends partway underneath the drain-facing side of the gate can be employed in conjunction with substantially any type of lateral MOS device design. By way of some nonlimiting illustrative examples, in some variant lateral MOS designs it is contemplated: to omit one or both illustrated doped regions 16 and/or 18; for the drift region to extend underneath the p-type well; to add an additional p type region embedded in the p-type well 18 and contacting the n′ source 12 to suppress the body effect; to reverse the doping polarities of the lateral MOS (i.e., switch the n-type regions to be p-type and vice versa); various combinations thereof; and/or so forth.

The sidewall of the illustrative gate 20 is a rectangular cylindrical sidewall having four sides: a first side 30 (i.e., source-facing side 30); a second side 32 (i.e., drain-facing side 32); and third and fourth sides 34 and 36 each extending between the source-facing and drain-facing sides 30 and 32. The first (source-facing) side 30 of the gate 20 and the second (drain-facing) side 32 of the gate 20 are opposite sides of the rectangular cylindrical sidewall. The source region 12 is disposed laterally offset from the gate on the first (i.e., source-facing) side 30 of the gate 20, and the drain region 14 is disposed laterally offset from the gate 20 on the second (i.e., drain-facing) side 32 of the gate 20.

A dielectric layer 40 circumferentially coats all four sides 30, 32, 34, 36 of the rectangular cylindrical sidewall of the gate 20. An extension 40E of the sidewall-coating dielectric layer 40 extends partway underneath the second side 32 of the gate 20. The side-sectional view of FIG. 1 shows the extension 40E of the dielectric layer 40 in a side-sectional view. The top view of FIG. 2 shows the extension 40E of the dielectric layer 40 by way of a hidden line. In the illustrative example, the extension 40E of the dielectric layer 40 extends partway underneath the second (drain-facing) side 32 of the gate 20; there is no corresponding extension that extends underneath the first (source-facing) side 30 of the gate. As seen in FIG. 2, the extension 40E of the dielectric layer 40 extends along the length of the second (drain-facing) side 32 of the gate 40. That is, in some embodiments the length of the extension 40E of the dielectric layer 40 along the Y direction indicated in FIG. 2 is coextensive with the length of the second (drain-facing) side 32 of the gate 40 along the Y direction.

As further seen in FIG. 2, there are also no corresponding extensions that extend underneath the connecting sides 36 and 38. Said another way, the dielectric layer 40 circumferentially coats the sidewall of the gate 20, and the extension 40E of the dielectric layer 40 extends partway underneath the gate 20 only on the second (drain-facing) side 32 of the gate 20. Furthermore, as seen in the side sectional view of FIG. 1, the dielectric layer 40 coats the sidewall of the gate 20, but does not coat the top of the gate 20, so as to provide access to the gate 20 for applying the control voltage Vtg. In the embodiment shown in FIG. 1, an optional additional spacer 42 may be coated onto the dielectric layer 40. (Note, the spacer 42 is not shown in the top view of FIG. 2 to emphasize the structure of the gate 20 and dielectric layer 40 and extension 40E of the dielectric layer 40).

Without loss of generality, for descriptive purposes axes or directions of a Cartesian coordinate system are labeled in FIGS. 1 and 2, including an X-axis or direction, a Y-axis or direction, and a Z-axis or direction. The side sectional view of FIG. 1 is taken along an X-Z plane, and the top view of FIG. 2 is a view along the −Z direction. FIG. 1 also illustrates a plot of the electric field (E-field) versus X position along the surface of the base semiconductor 10 during reverse biasing of the LDMOS device. A coordinate xₚ indicated in this plot corresponds to the X position of the second (drain-facing) side 32 of the gate 20. The plot of FIG. 1 represents the result of electromagnetic simulations of an operating LDMOS device, via which it was found that the peak electric field during reverse bias occurs at or near the X position xₚ and close to the surface of the base semiconductor 10. This location of the peak reverse bias electric field is indicated in FIG. 1 as a location (xₚ,zₚ). In simulations conducted modeling the peak electric field at the location (xₚ, zₚ) with and without the extension 40E of the dielectric layer 40, it was found that this peak was lowered by including the extension 40E of the dielectric layer 40. In experimental comparisons of actually fabricated LDMOS devices with and without the extension 40E of the dielectric layer 40, it was found the breakdown voltage V_{bd} was increased by about 3.5% by inclusion of the extension 40E of the dielectric layer 40. The increase is breakdown voltage V_{bd} is believed to be attributable to the reduced peak electric field at the second (drain-facing) edge 32, i.e., at the location (xₚ,zₚ).

In some nonlimiting illustrative embodiments, the base semiconductor 10 comprises silicon, the gate oxide 22 comprises silicon dioxide, the gate 20 comprises a metal, a metal alloy, a polycrystalline silicon material, a silicide material, or a combination of silicide and polycrystalline silicon materials, and the dielectric layer 40 (including the extension 40E) comprises an oxide material, a nitride material, a carbide material, an oxynitride material, an oxycarbide material, a nitride carbide material, or a polymer material. These are merely some nonlimiting illustrative examples. As the improvement (e.g., increase in breakdown voltage V_{bd}) is believed to be due to the reduction in the peak electric field due to the geometrical change at the second (drain-facing) side 32 introduced by the extension 40E, improvement in performance metrics such as the breakdown voltage are expected to be attained by inclusion of the extension 40E of the dielectric layer 40 independently of the materials of the lateral MOS device, and independently of the detailed structure (e.g., doping profiles 16, 18).

A further advantage is that these advantages of including the extension 40E of the dielectric layer 40 are attainable with minimal modification of the lateral MOS device fabrication workflow.

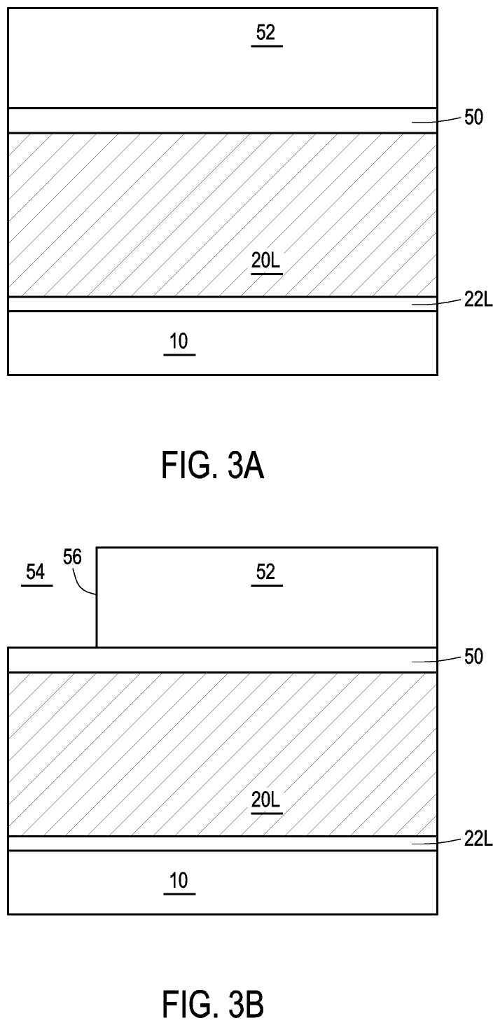

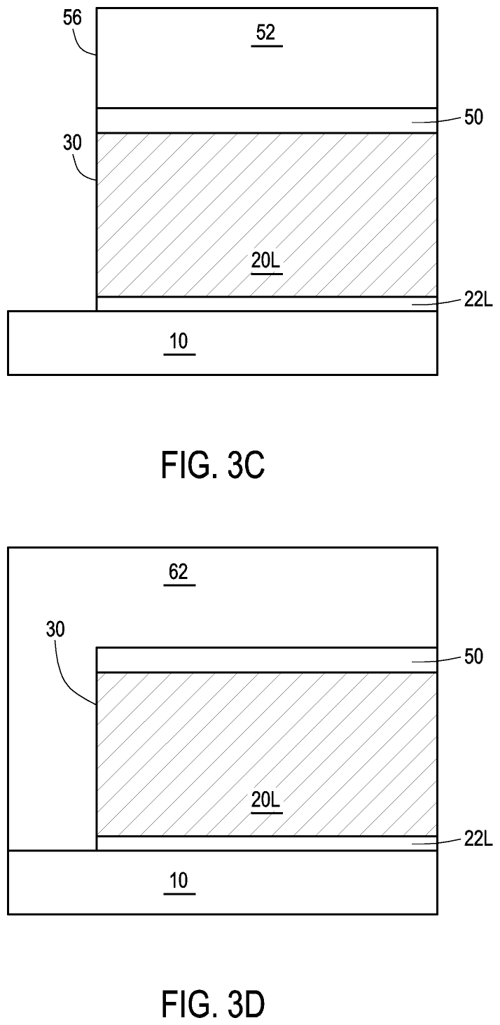

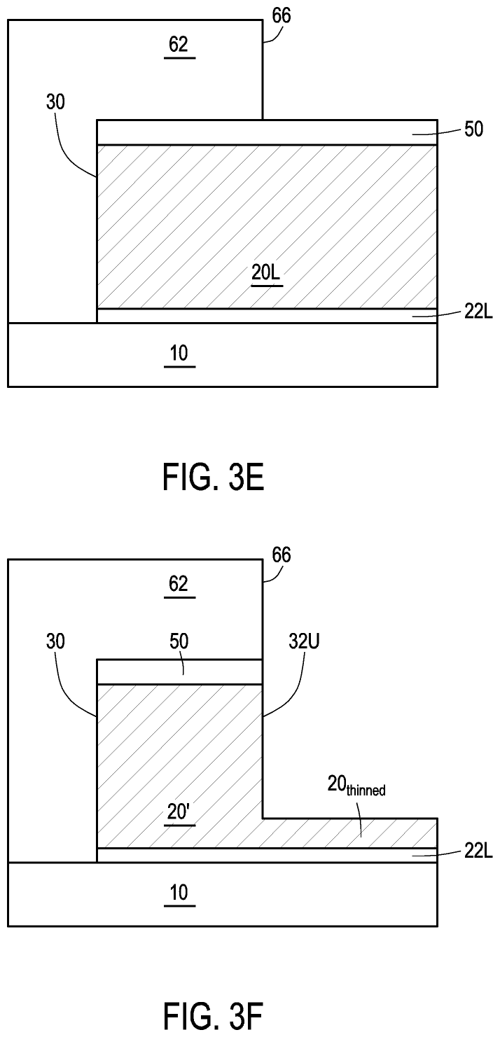

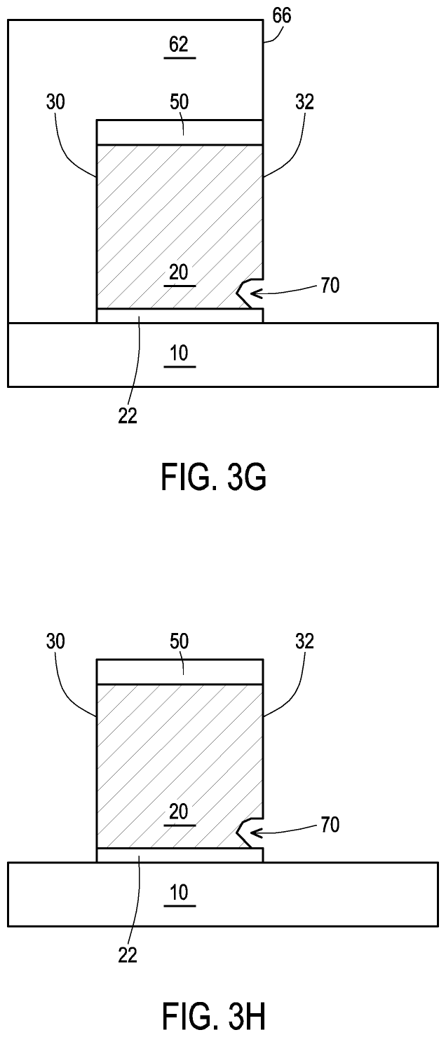

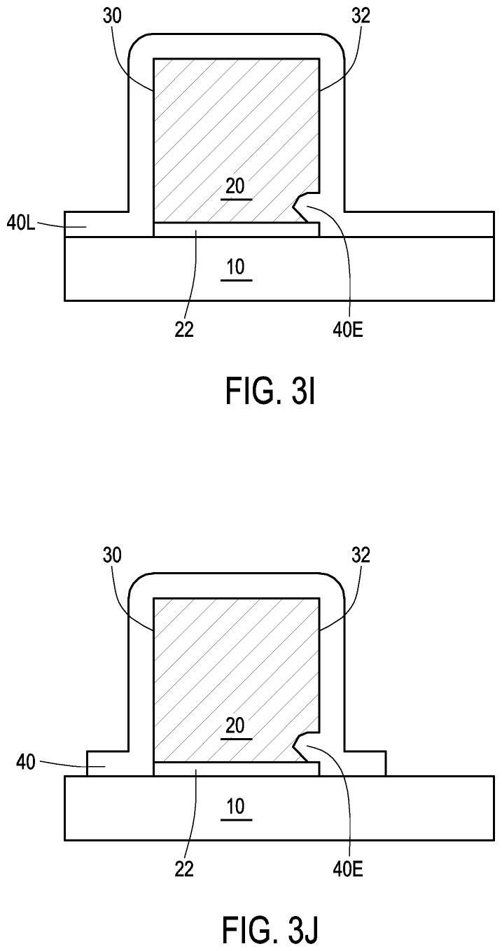

FIGS. 3A, 3B, 3C, 3D, 3E, 3F, 3G, 3H, 3I, and 3J diagrammatically illustrate side sectional views of the gate region of a lateral MOS device at successive fabrication stages. As this fabrication process relates to formation of the gate 20 and particularly the fabrication of the dielectric layer 40 and its extension 40E, doping steps relating to formation of the doped regions of the lateral MOS device (e.g., doped regions 16 and 18 shown in the nonlimiting illustrative example of FIG. 1) are not discussed. However, as is known in the art, in some lateral MOS device fabrication workflows the gate may be utilized for controlling the spatial extent of certain doped regions. Hence, doping steps (e.g., dopant diffusion and/or dopant implantation steps) may be interspersed amongst the steps depicted in successive FIGS. 3A-3J.

FIG. 3A illustrates a side sectional view of the under-fabrication gate region after deposition of a gate oxide layer 22L and a gate layer 20L (which will be patterned to form the gate oxide 22 and the gate 20, respectively), a hard mask layer 50, and a photoresist layer 52. The gate oxide layer 22L can be a silicon dioxide layer formed by thermal oxidation, chemical vapor deposition (CVD), atomic layer deposition (ALD), or another suitable technique. Other oxide materials are also contemplated for the gate oxide layer 22L. The gate layer 20L may comprise a metal, a metal alloy, a polycrystalline silicon material, a silicide material, or a combination of silicide and polycrystalline silicon materials, by way of some nonlimiting illustrative examples, and may be deposited on the gate oxide layer 22L by CVD or another deposition technique suitable for the chosen gate material. The hard mask 50 may, for example, be disposed on the gate layer 20L by depositing the hard mask layer 50 comprising a silicon oxynitride by CVD, although other suitably hard materials and corresponding deposition techniques are also contemplated. The photoresist layer 52 can be formed by a spin-on process, by way of nonlimiting illustrative example.

FIG. 3B illustrates a side sectional view of the under-fabrication gate region after patterning of the photoresist 52 by photolithographic exposure and developing to form an opening 54 whose edge 56 is aligned with the first (source-facing) edge 30 of the under-fabrication gate.

FIG. 3C illustrates a side sectional view of the under-fabrication gate region after etching of the gate layer 20L to form the first (source-facing) side 30 of the gate. This etching step also etches the portion of the hard mask 50 overlying the removed portion of the gate layer, and the portion of the gate oxide layer 22L underlying the removed portion of the gate layer. The etching step suitably uses an anisotropic dry etch providing high aspect ratio etching, such as reactive ion etching (RIE) or deep reactive ion etching (DRIE), so that the formed first (source-facing) side 30 of the gate is aligned with the edge 56 of the opening 54 in the patterned photoresist.

After FIG. 3C, the patterned photoresist 52 is stripped using a suitable photoresist stripping solvent or the like.

FIG. 3D illustrates a side sectional view of the under-fabrication gate region after the (first) photoresist 52 is stripped and a (second) photoresist layer 62 is deposited by a spin-on process or the like.

FIG. 3E illustrates a side sectional view of the under-fabrication gate region after patterning of the (second) photoresist 62 by photolithographic exposure and developing to form an opening 64 whose edge 66 is aligned with the second (drain-facing) edge 32 of the under-fabrication gate.

FIG. 3F illustrates a side sectional view of the under-fabrication gate region after partial etching of the gate layer 20L to form an upper portion 32U of the second (drain-facing) side 32 of the gate. This etching step also etches the portion of the hard mask 50 overlying the removed portion of the gate layer, and suitably uses an anisotropic dry etch providing high aspect ratio etching, such as RIE or DRIE, so that the formed upper portion 32U of the second (drain-facing) side of the gate is aligned with the edge 66 of the opening 64 in the patterned photoresist.

Notably, unlike the etch step illustrated in FIG. 3C for forming the first (source-facing) side 30 of the gate, the etch process illustrated in FIG. 3F does not completely remove the gate layer underneath the opening 64. Rather, the etch is a first etch process of a two-stage etch process, and this first stage etch process leaves a thinned portion 20_{thinned} of the gate layer extending laterally away from the (at this point incompletely exposed) drain-facing side of the gate (i.e., the upper portion 32U of the drain-facing side). A mostly formed gate 20′ is formed at this stage of the fabrication process, except for the remaining thinned portion 20_{thinned} of the gate layer which extends away from the now mostly formed gate 20′.

FIG. 3G illustrates a side sectional view of the under-fabrication gate region after removal of the remaining thinned portion 20_{thinned} of the gate layer by a second stage etch process of the two-stage etch process. The second etching process removes the thinned portion 20_{thinned} of the gate layer, and also removes a portion of the gate layer underneath the edge to form a cavity 70 extending partway underneath the second side 32 of the (now fully formed) gate 20. In the illustrative example, the cavity 70 extends partway underneath the second side 32 of the gate 20. To accomplish these dual goals of removing the thinned portion 20_{thinned} of the gate layer and also forming the self-aligned cavity 70, the second etch process is an isotropic etch process, or is a less anisotropic etch process than the first etch process used to expose the upper portion 32U of the second side 32 (see FIG. 3F).

To this end, in some embodiments the first dry etch forming the upper portion 32U (FIG. 3F) is performed with etch parameters (e.g., RF field) chosen to provide the desirably high aspect ratio anisotropic etching. The first etch is then followed by a second etch (FIG. 3G) which in this example may be a dry etching technique such as RIE or DRIE, but performed with different etch parameters to be less anisotropic (i.e., provide less high aspect ratio etching) than the first etch. This more isotropic second etch process thus provides a significant lateral etch direction component so as to form the cavity 70. It will be appreciated that the dimensions of the cavity 70 can be adjusted by adjusting process parameters such as the etch time of the first etch process (where a shorter first etch will leave a larger thickness of the remaining thinned portion 20_{thinned} so that the second etch produces a higher cavity 70 in the Z-direction) and aspect ratio of the second etch process, where lower aspect ratio corresponds to a less anisotropic second etch (or, equivalently, a more isotropic second etch) and hence a deeper cavity 70 in the X-direction.

In the foregoing example, the first and second etch processes are both dry etching processes, and in some embodiments may be performed using a single etch recipe in a single dry etching chamber, with the recipe switching the etch parameters to switch from the more anisotropic first etch to the less anisotropic (or more isotropic) second etch. However, other approaches are contemplated, such as using different etching modalities for the first and second etch processes. For example, in another embodiment the second etch process is implemented as an isotropic wet etching process.

FIG. 3H illustrates a side sectional view of the under-fabrication gate region after the (second) patterned photoresist 62 is stripped using a suitable photoresist stripping solvent or the like. As seen in FIG. 3H, this leaves the fully formed gate 20 with the first (source-facing) side 30 and the second (drain-facing) side 32 with the cavity extending partway underneath the second side of the gate.

FIG. 3I illustrates a side sectional view of the under-fabrication gate region after deposition of a dielectric layer 40L. The dielectric layer 40L is suitably deposited as a conformal blanket dielectric layer by CVD, or formed by thermal oxidation, or so forth. The dielectric layer 40L may, for example, comprise an oxide material, a nitride material, a carbide material, an oxynitride material, an oxycarbide material, a nitride carbide material, or a polymer material. The dielectric layer 40L is formed using an isotropic (or close to isotropic) deposition process so that the dielectric material of the dielectric layer 40L is deposited approximately conformally, including coating the sidewall of the gate 20 and filling the cavity 70 extending partway underneath the second side 32 of the gate 20. The dielectric material filling the cavity 70 forms the extension 40E of the sidewall-coating dielectric layer.

FIG. 3J shows a side sectional view of the gate region after subsequent etching of portions of the dielectric layer 40L to leave the dielectric layer 40 circumferentially coating all four sides 30, 32, 34, 36 of the rectangular cylindrical sidewall of the gate 20, and with the extension 40E of the sidewall-coating dielectric layer 40 extending partway underneath the second side 32 of the gate 20. In the illustrative example of FIG. 3J, the extension 40E of the sidewall-coating dielectric layer 40 extends partway underneath the second side 32 of the gate 20, and hence is disposed between the gate oxide 22 and the second side 32 of the gate 20.

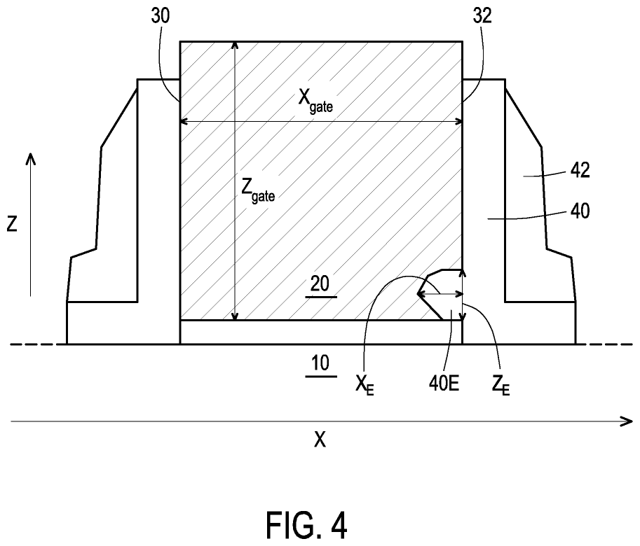

With reference now to FIG. 4, a side sectional view is shown of the gate region of a lateral MOS device. FIG. 4 depicts the gate oxide 22 disposed on the base semiconductor 10, and the gate 20 disposed on the gate oxide 22 In FIG. 4. Also labeled in FIG. 4 are the first (source-facing) side 30 and second (drain-facing) side 32 of the gate 20, the sidewall-coating dielectric layer 40 with the extension 40E, and the optional spacer 42. Further, certain dimensions are indicated in FIG. 4. The dimension x_{gate} denotes the width of the gate 20 along the channel direction. Put another way, dimension x_{gate} denotes the lateral spacing between the first side 30 and the second side 32 of the gate 20. A dimension z_{gate} denotes a height of the gate 20. The extension 40E of the dielectric layer 40 underneath the second side 32 of the gate 20 is also dimensioned: a dimension x_{E} denotes the lateral distance of the extension 40E of the dielectric layer 40 underneath the second side 32 of the gate 20, while a dimension z_{E} denotes the height of the extension 40E of the dielectric layer 40.

In some nonlimiting illustrative embodiments, a ratio x_{E}/x_{gate} of the lateral distance x_{E} of the extension 40E of the dielectric layer 40 underneath the second side 32 of the gate 20 to the lateral spacing x_{gate} between the first and second sides 30 and 32 of the gate 20 is between 0.01 and 0.1. The increase in the breakdown voltage V_{bd} due to the extension 40E is expected to increase with larger values of this ratio x_{E}/x_{gate}. However, if the ratio x_{E}/x_{gate} is too large then this is expected to increase risk of damage to the structural integrity of the gate 20. Hence, selecting 0.01≤x_{E}/x_{gate}≤0.1 is expected to provide a suitable balance between the desire to increase V_{bd} and maintaining yield of the fabricated lateral MOS devices.

In some nonlimiting illustrative embodiments, the ratio x_{E}/x_{gate} of the lateral distance x_{E} of the extension 40E of the dielectric layer 40 underneath the second side 32 of the gate 20 to the lateral spacing x_{gate} between the first and second sides 30 and 32 of the gate 20 is at least 0.01.

In some nonlimiting illustrative embodiments, a ratio z_{E}/z_{gate} of the height z_{E} of the extension 40E of the dielectric layer 40 to the height z_{gate} of the gate 20 is between 0.01 and 0.5. The increase in the breakdown voltage V_{bd} due to the extension 40E is expected to increase with larger values of this ratio z_{E}/z_{gate}. However, if the ratio z_{E}/z_{gate} is too large then this is expected to increase risk of damage to the structural integrity of the gate 20. Hence, selecting 0.01≤z_{E}/z_{gate}≤0.5 is expected to provide a suitable balance between the desire to increase V_{bd} and maintaining yield of the fabricated lateral MOS devices.

In some nonlimiting illustrative embodiments, a ratio z_{E}/z_{gate} of the height z_{E} of the extension 40E of the dielectric layer 40 to the height z_{gate} of the gate 20 is at least 0.01.

In the following, some further embodiments are described.

In a nonlimiting illustrative embodiment, a method of fabricating a lateral metal oxide semiconductor (MOS) device is disclosed. The method comprises: forming a source of the lateral MOS device in a base semiconductor; forming a drain of the lateral MOS device; disposing a gate oxide layer on the base semiconductor; disposing a gate layer on the gate oxide layer; performing photolithographically patterned etching of the gate layer to form a first side of a gate facing the source of the lateral MOS device; performing photolithographically patterned etching of the gate layer to form a second side of the gate facing the drain of the lateral MOS device and to etch a cavity extending partway underneath the second side of the gate; and forming a dielectric layer at least on the first and second sides of the gate and filling the cavity extending partway underneath the second side of the gate.

In a nonlimiting illustrative embodiment, a lateral MOS device comprises: a base semiconductor; a gate oxide disposed on the base semiconductor; a gate disposed on the gate oxide; a source region disposed laterally offset from the gate on a first side of the gate; a drain region disposed laterally offset from the gate on a second side of the gate; and a dielectric layer disposed on a sidewall of the gate and including an extension of the dielectric layer that extends partway underneath the second side of the gate.

In a nonlimiting illustrative embodiment, a method of fabricating a gate of a lateral MOS device is disclosed. The method comprises: disposing a gate layer on a gate oxide layer; performing photolithographically patterned etching of the gate layer to form a first side of the gate facing the source of the lateral MOS device; performing photolithographically patterned etching of the gate layer to form a second side of the gate facing the drain of the lateral MOS device and to etch a cavity extending partway underneath the second side of the gate, including: (i) a first etch that removes an upper portion of the gate layer to expose an upper portion of the second side of the gate, and (ii) a second etch that removes a lower portion of the gate layer to complete exposure of the second side of the gate and that further removes a portion of the gate layer underneath the second side of the gate to form a cavity extending partway underneath the second side of the gate; and forming a dielectric layer at least on the first and second sides of the gate and filling the cavity extending partway underneath the second side of the gate.

In a nonlimiting illustrative embodiment, in fabricating a MOS device, source and drain regions are formed by n-type doping of a base semiconductor. A gate oxide layer is disposed on the base semiconductor, and a gate layer on the gate oxide layer. Photolithographically patterned etching of the gate layer forms a first side of the gate. Photolithographically patterned etching of the gate layer forms a second side of the gate, and also etches the cavity extending partway underneath the second side of the gate. A dielectric layer is formed at least on the first and second sides of the gate and filling the cavity extending partway underneath the second side of the gate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a lateral metal oxide semiconductor (MOS) device, the method comprising:
forming a source of the lateral MOS device in a base semiconductor;
forming a drain of the lateral MOS device;
disposing a gate oxide layer on the base semiconductor;
disposing a gate layer on the gate oxide layer;
performing photolithographically patterned etching of the gate layer to form a first side of a gate facing the source of the lateral MOS device;
performing photolithographically patterned etching of the gate layer to form a second side of the gate facing the drain of the lateral MOS device and to etch a cavity extending partway underneath the second side of the gate; and
forming a dielectric layer at least on the first and second sides of the gate and filling the cavity extending partway underneath the second side of the gate.

2. The method of claim 1, wherein the performing of photolithographically patterned etching of the gate layer to form the second side of the gate and to etch the cavity extending partway underneath the second side of the gate includes:
disposing a hard mask layer on the gate layer;
disposing a photoresist layer on the hard mask layer;
patterning the photoresist layer and the hard mask layer to form an edge;
performing a first etching process to remove an upper portion of the gate layer in a region extending up to the edge, the first etching process forming an upper portion of the second side of the gate aligned with the edge and leaving a thinned portion of the gate layer extending laterally away from the edge;
performing a second etching process to remove the thinned portion of the gate layer to form a lower portion of the second side of the gate aligned with the edge and to remove a portion of the gate layer underneath the edge to form the cavity extending partway underneath the second side of the gate.

3. The method of claim 2, wherein the first etching process is more anisotropic than the second etching process.

4. The method of claim 2, wherein:
the first etching process is an anisotropic dry etching process; and
the second etching process is a dry etching process that is isotropic or less anisotropic than the first etching process.

5. The method of claim 2, wherein the disposing of the hard mask layer on the gate layer comprises depositing the hard mask layer comprising a silicon oxynitride by chemical vapor deposition.

6. The method of claim 1, wherein the forming of the dielectric layer at least on the first and second sides of the gate and filling the cavity extending partway underneath the second side of the gate comprises:
depositing the dielectric layer by chemical vapor deposition or forming the dielectric layer by thermal oxidation.

7. The method of claim 1, wherein:
the base semiconductor comprises silicon;
the gate oxide comprises silicon dioxide;
the gate comprises a metal, a metal alloy, a polycrystalline silicon material, a silicide material, or a combination of silicide and polycrystalline silicon materials; and
the dielectric layer comprises an oxide material, a nitride material, a carbide material, an oxynitride material, an oxycarbide material, a nitride carbide material, or a polymer material.

8. The method of claim 1, wherein the performing of photolithographically patterned etching of the gate layer to form the first side of the gate does not include etching a cavity underneath the first side of the gate.

9. A lateral metal oxide semiconductor (MOS) device comprising:
a base semiconductor;
a gate oxide disposed on the base semiconductor;
a gate disposed on the gate oxide;
a source region disposed laterally offset from the gate on a first side of the gate;
a drain region disposed laterally offset from the gate on a second side of the gate; and
a dielectric layer disposed on a sidewall of the gate and including an extension of the dielectric layer that extends partway underneath the second side of the gate.

10. The lateral MOS device of claim 9, wherein the dielectric layer circumferentially coats the sidewall of the gate and the extension of the dielectric layer extends partway underneath the gate only on the second side of the gate.

11. The lateral MOS device of claim 9, wherein:
the sidewall of the gate is a rectangular cylindrical sidewall having four sides including the first side of the gate and the second side of the gate which are opposite sides of the rectangular cylindrical sidewall;
the dielectric layer circumferentially coats all four sides of the rectangular cylindrical sidewall; and
the extension of the dielectric layer extends partway underneath the second side of the gate and does not extend underneath the first side of the gate.

12. The lateral MOS device of claim 9, wherein the lateral MOS device comprises a lateral double-diffused MOS (LDMOS) device that includes a double diffused region comprising:
a first n-type doped region forming a drift region of the LDMOS, and
a second n-type doped region disposed in the first n-type region and forming the drain region, the second n-type doped region having a higher n-type doping concentration than the first n-type doped region.

13. The lateral MOS device of claim 9, wherein the dielectric layer and the extension of the dielectric layer comprises an oxide material, a nitride material, a carbide material, an oxynitride material, an oxycarbide material, a nitride carbide material, or a polymer material.

14. The lateral MOS device of claim 13, wherein:
the base semiconductor comprises silicon;
the gate oxide comprises silicon dioxide; and
the gate comprises a metal, a metal alloy, a polycrystalline silicon material, a silicide material, or a combination of silicide and polycrystalline silicon materials.

15. The lateral MOS device of claim 9, wherein a ratio of a lateral distance of the extension of the dielectric layer underneath the second side of the gate to a lateral spacing between the first and second sides of the gate is between 0.01 and 0.1.

16. The lateral MOS device of claim 9, wherein a ratio of a height of the extension of the dielectric layer to a height of the gate is between 0.01 and 0.5.

17. A method of fabricating a gate of a lateral metal oxide semiconductor (MOS) device, the method comprising:
disposing a gate layer on a gate oxide layer;
performing photolithographically patterned etching of the gate layer to form a first side of the gate of the lateral MOS device;
performing photolithographically patterned etching of the gate layer to form a second side of the gate and to etch a cavity extending partway underneath the second side of the gate, including:
a first etch that removes an upper portion of the gate layer to expose an upper portion of the second side of the gate, and
a second etch that removes a lower portion of the gate layer to complete exposure of the second side of the gate and that further removes a portion of the gate layer underneath the second side of the gate to form the cavity extending partway underneath the second side of the gate; and
forming a dielectric layer at least on the first and second sides of the gate and filling the cavity extending partway underneath the second side of the gate.

18. The method of claim 17, wherein the second etch is isotropic or is less anisotropic than the first etch.

19. The method of claim 18, wherein the first etch is a dry etch and the second etch is a dry etch.

20. The method of claim 18, wherein:
the gate layer comprises a polysilicon layer, and
the dielectric layer comprises an oxide material, a nitride material, a carbide material, an oxynitride material, an oxycarbide material, a nitride carbide material, or a polymer material.
